(19) United States
(12) Patent Application Publication
(10) Pub. No.: US 2009/0115735 A1
(43) Pub. Date: May 7, 2009

(54) Sensor with pressure-induced varied capacitance

(75) Inventor: Kai-Lan Chuang, Tainan (TW)

Correspondence Address: STOUT, UXA, BUYAN & MULLINS LLP, 4 VENTURE, SUITE 300, IRVINE, CA, 92618, US

(73) Assignee: HIMAX TECHNOLOGIES LIMITED

(21) Appl. No.: 11/983,060

(22) Filed: Nov. 6, 2007

(51) Int. Cl. H01L 27/00; G06F 3/041

(52) U.S. Cl. 345/173; 257/415; 257/E27.009

(57) ABSTRACT

A sensor with pressure-induced varied capacitance is disclosed. Each sensor pixel circuit of the sensor includes a touch capacitor, a charge TFT for storing charge at the touch capacitor according to a previous scan line, and a readout TFT for reading out voltage across the touch capacitor according to a present scan line.

### BACKGROUND OF THE INVENTION

1. Field of the Invention

The present invention generally relates to a TFT sensor, and more particularly to a TFT sensor with varied capacitance induced by pressure.

2. Description of Related Art

A touch panel integrated with a liquid crystal display (LCD) has advantages of easier and faster entry of information, and more interactive access, and thus obtains more use in portable devices such as mobile phones, personal digital assistants (PDA) or notebook computers.

In the conventional display with the touch panel, the touch panel is attached to the front of the display, which has the disadvantages of complicated assembly, increased weight, and reduced display transmission. For overcoming these disadvantages, another touch technology is disclosed to use a sensor array embedded in the thin-film-transistor (TFT) structure of an LCD.

It has been an object in the pertinent art to propose novel sensor pixel circuit architecture of the touch panel that is more simplified, more integrated while maintaining preciseness in capturing an image.

### SUMMARY OF THE INVENTION

In view of the foregoing, it is an object of the present invention to provide a sensor with pressure-induced varied capacitance capable of being embedded in a touch panel and integrated with a display to precisely determine the location and image of finger(s) or other object(s).

According to the object, the present invention provides a sensor with pressure-induced varied capacitance. An active matrix area has a number of sensor pixel circuits arranged in matrix form. Scan lines and readout lines are arranged in the active matrix area such that the scan lines and the readout lines respectively cross each other at one of the sensor pixel circuits. The sensor pixel circuit includes a touch capacitor, a charge TFT for storing charge at the touch capacitor according to a previous scan line, and a readout TFT for reading out voltage across the touch capacitor according to a present scan line. According to one embodiment, a scan driver sequentially asserts the scan lines; and a readout circuit analyzes analog signals outputted from the active matrix area, and then converts the analog signals into digital signals. An image processing circuit is then used to determine the location and image of the object(s).

### BRIEF DESCRIPTION OF THE FIGURES

FIG. 1 illustrates a block diagram of a TFT finger sensor according to one embodiment of the present invention;

FIG. 2 illustrates the architecture of the sensor pixel circuits of FIG. 1 according to one embodiment of the present invention;

FIG. 3 illustrates one embodiment of the readout circuit in FIG. 1;

FIG. 4 shows an exemplary timing diagram of associated signals of the finger sensor according to the embodiment of FIG. 2 and FIG. 3; and

FIG. 5 shows a flow chart illustrating a method of sensing a finger according to one embodiment of the present invention.

### DETAILED DESCRIPTION OF THE INVENTION

There is one type of sensor that has varied capacitance induced by pressure of a finger on the sensor. This type of sensor utilizes the principle that the capacitance varies inversely proportional to the separation between two plates of the sensor. For example, the sensor pressed by the finger will increase its capacitance due to the decreased separation between the plates.

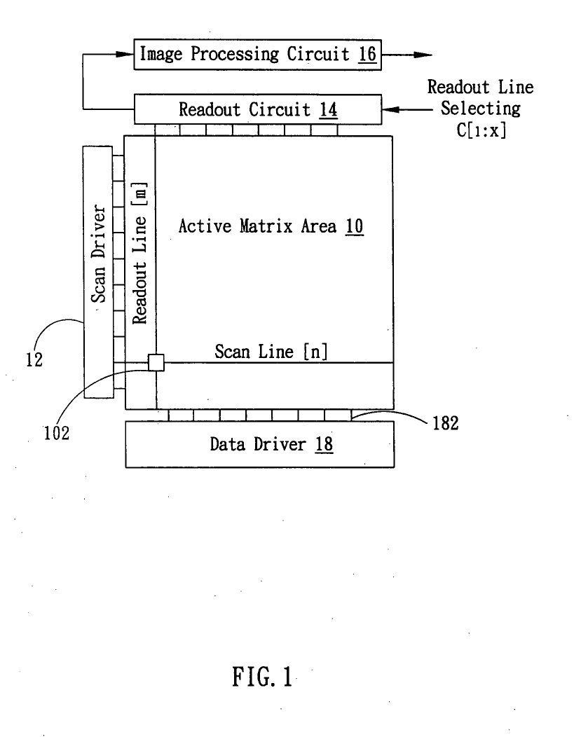

FIG. 1 illustrates a block diagram of a thin-film-transistor (TFT) finger sensor, particularly a sensor with pressure-induced varied capacitance, according to one embodiment of the present invention. The TFT finger sensor is embedded in a touch panel, which is further integrated with a display (not shown), such as a liquid crystal display (LCD) in this embodiment. It is appreciated by those skilled in the art that the finger sensor in this exemplary embodiment is used to capture the image of a finger or fingers, whilst the “finger” sensor is definitely not limited to capturing the finger(s).

In FIG. 1, an active matrix area 10 contains a number of sensor pixel circuits (or sensor pixel cells) 102 arranged in matrix form for detecting the finger. The active matrix area 10 also contains a number of display pixel circuits (not shown), and some of the display pixel circuits are associatively integrated with the sensor pixel circuits. In practice, the quantity of the sensor pixel circuits in the active matrix area 10 is less than the quantity of the display pixels circuits. There are a number of (horizontal) scan lines and (vertical) readout lines arranged in the active matrix area 10 such that each sensor pixel circuit 102 at which one scan line crosses one readout line. A scan driver 12 asserts the scan lines by sequentially selecting the scan lines one at a time. In other words, a row of sensor pixel circuits 102 is asserted by associated scan line at a time. A readout circuit 14 analyzes analog signals outputted from the active matrix area 10, and then converts the analog signals into digital signals. The converted digital signals are forwarded to an image processing circuit 16 to determine the location and image of a finger or fingers. Data driver 18 is specifically used for driving the display pixel circuits via data lines 182 to display image on the LCD.

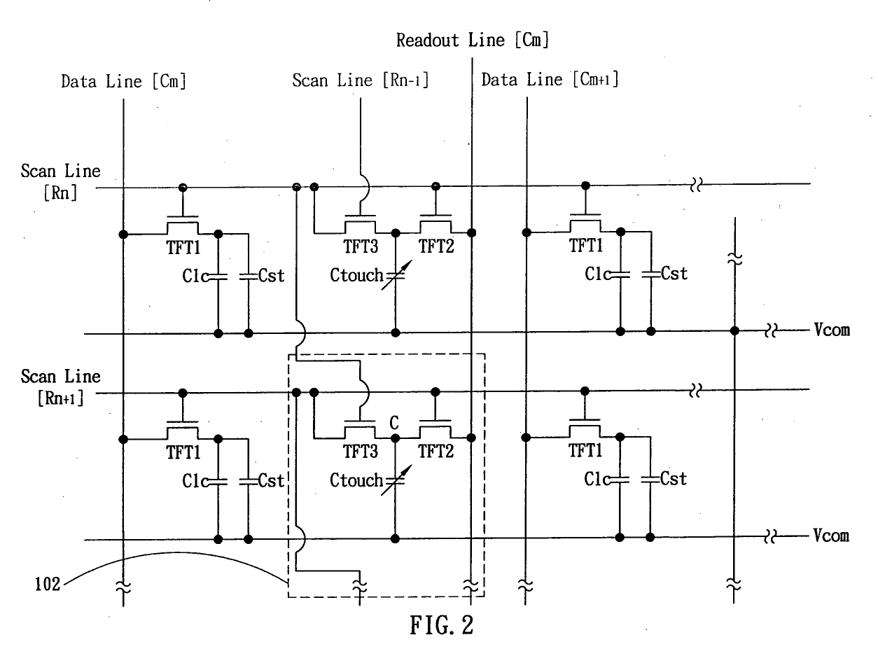

FIG. 2 illustrates the architecture of the sensor pixel circuits 102 of FIG. 1 according to one embodiment of the present invention. In the figure, only two sensor pixel circuits 102 are shown for the purpose of illustration, while other sensor pixel circuits 102 not shown could be well built in the same manner. Display pixel circuits each consisting of a TFT1 and capacitors C_{Ic} and Cₛₜ are also shown in the figure. In the embodiment, Scan Lines are commonly used among the display pixel circuits and the sensor pixel circuits 102, while the display pixel circuits use specific data line, e.g., Data Line [Cₘ], for display, and the sensor pixel circuits use specific readout line, e.g., Readout Line [Cₘ], for sensor.

Each sensor pixel circuit 102 includes a charge TFT (TFT3), a readout TFT (TFT2), and a touch capacitor C_{touch} connected as shown. A scan line is associated with and connected to the readout TFTs (TFT2) of all of the sensor pixel circuits 102 on the same row. In this exemplary figure, Scan Line [Rₙ₊₁] is connected to the readout TFTs (TFT2) of the sensor pixel circuits 102 on the (n+1)-th row. A scan line of previous row is associated with and connected to the charge TFTs (TFT3) of all of the sensor pixel circuits 102 on the same row. In this exemplary figure, Scan Line [Rₙ] is connected to the charge TFTs (TFT3) of the sensor pixel circuits 102 on the (n+1)-th row. A number of readout lines each is respectively associated with and connected to corresponding sensor pixel circuits 102 on the same column. In this exemplary figure, Readout Line [Cₘ] is connected to sensor pixel circuits 102 on the m-th column.

Still referring to FIG. 2, specifically speaking, with respect to the readout TFT (TFT2), one of the source/drain is electrically connected to the associated Readout Line [Cₘ], the gate is electrically connected to the associated Scan Line [Rₙ₊₁] of the present row, and the other one of the source/drain is electrically connected to the charge TFT (TFT3) and the touch capacitor C_{touch} at a node C. With respect to the charge TFT (TFT3), one of the source/drain is electrically connected to the readout TFT (TFT2) at the node C, the gate is electrically connected to the associated Scan Line [Rₙ] of previous row, and the other one of the source/drain is electrically connected to the associated Scan Line [Rₙ₊₁] of the present row. With respect to the touch capacitor C_{touch}, one plate is electrically connected to the node C and the other plate is electrically connected to a common voltage V_{com}.

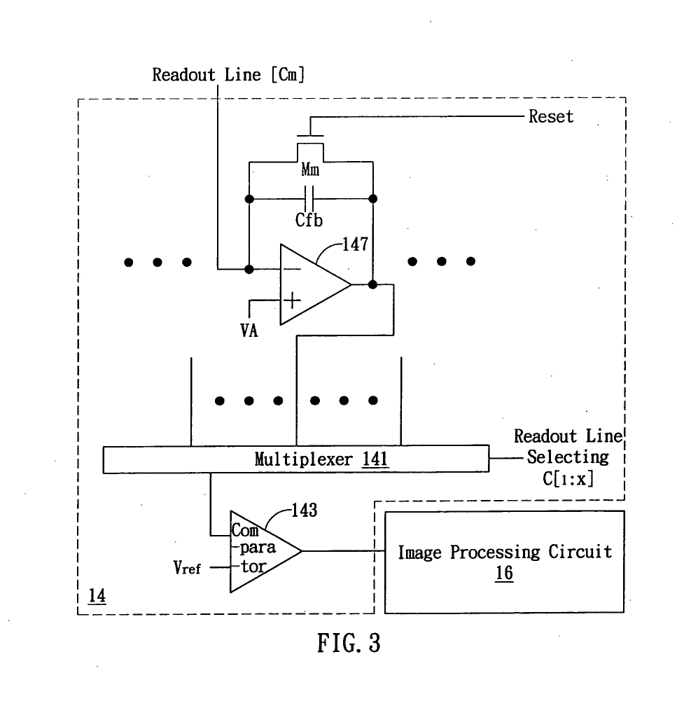

FIG. 3 illustrates one embodiment of the readout circuit 14 in FIG. 1. A number of readout lines respectively corresponding to columns of sensor pixel circuits are connected and inputted to integrating circuits (such as integrator operational amplifiers (OP-Amp)) 147. A feedback capacitor C_{fb} is connected between the output and the inverting input of each integrator OP-Amp 147, while the non-inverting input of the integrator OP-Amp 147 is connected with a predetermined reset voltage VA. The source and drain of a reset transistor M is connected across the ends of the feedback capacitor C_{fb}, and its gate electrode is connected to a Reset signal. The output of the integrator OP-Amp 147 is further connected to a multiplexer 141. One of the outputs of the integrator OP-Amps 147 is selected in turn according to Readout Line Selecting signal. The selected analog signal is converted into digital signal by comparing the selected analog signal with a predetermined reference voltage V_{ref} through a comparator 143, resulting in an N-bit output. In an exemplary embodiment, the output of the comparator 143 has one bit (i.e., N=1) to indicate either presence of a touched finger or the absence of a finger. The output of the comparator 143 is further fed to the image processing circuit 16 for further processing.

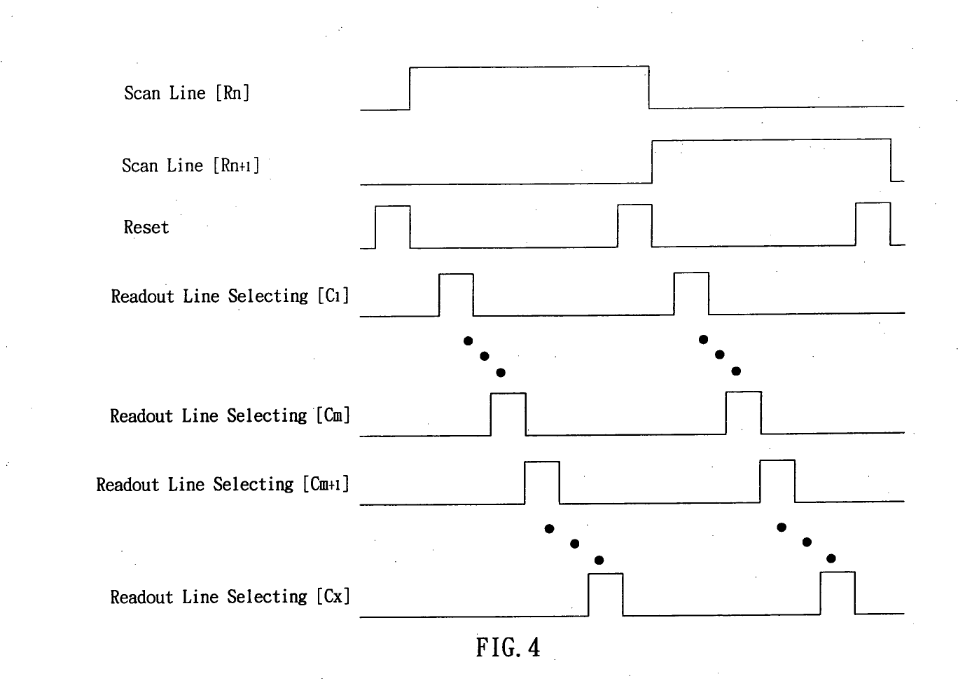

FIG. 4 shows an exemplary timing diagram of associated signals of the finger sensor according to the embodiment of FIG. 2 and FIG. 3. In one line scan, for example the line scan for the n-th row as shown in the figure, while the Scan Line [Rₙ] is asserted, Readout Line Selecting [C₁]-[Cₓ] signals (to the readout circuit 14) respectively associated with columns of sensor pixel circuits 102 are asserted in sequence. The Reset [n] signal is asserted at the end of the assertion of each scan line to reset the output of the integrator OP-Amp 147 to VA through the reset transistor M, and the integrator OP-Amp 147 is ready for performing integration for the next scan line.

The operation of the finger sensor of FIG. 2 and FIG. 3 will be specifically described below while referring to FIG. 4. When a Scan Line [Rₙ] is asserted, the charge TFTs (TFT3) on the next row (i.e., (n+1)-th row) are turned on, and charge QC is then stored at each touch capacitor C_{touch} due to an (un-asserted) gate-low voltage VGL at the unasserted Scan Line [Rₙ₊₁]. The voltage at the node C thus reaches VGL. The charge QC and the gate-low voltage VGL have the following relationship:

QC=C_{touch}*VGL

where the value of C_{touch} with presence of a touched finger is greater than the value of C_{touch} with absence of a finger, because the gap between electrode plates of the touch capacitor C_{touch} would be smaller if pressed by the finger or other objects.

Subsequently, when a next Scan Line [Rₙ₊₁] is asserted, the readout TFTs (TFT2) on the (n+1)-th row are turned on, and the voltage VGL at the node C is then readout through corresponding readout line. The readout voltage is then integrated by the integrator OP-Amp 147. The integrated output Vₒᵤₜ of the integrator OP-Amp 147 is:

$${V}_{out} = VA + \frac{( {V}_{ref} - V G L ) \times {C}_{touch}}{{C}_{fb}}$$

Therefore, the absence or presence of a finger could be distinguished according to different Vₒᵤₜ due to different C_{touch}.

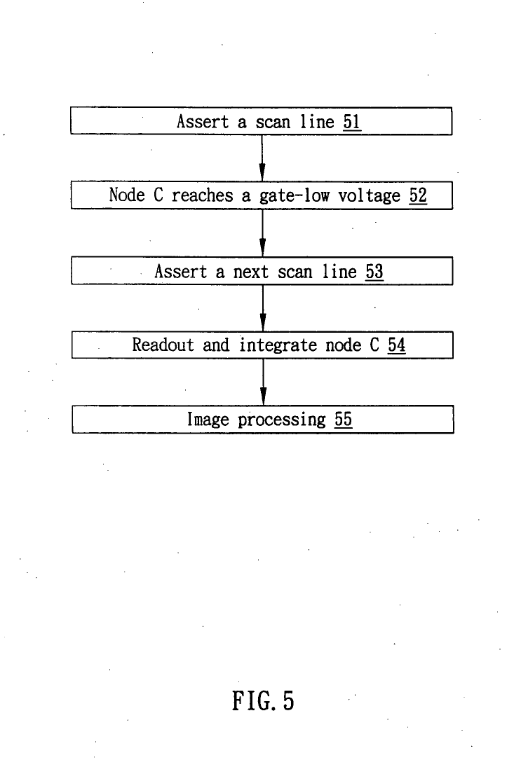

FIG. 5 shows a flow chart illustrating a method of sensing a finger according to one embodiment of the present invention. At the outset, in step 51, a Scan Line [Rₙ] is asserted, and the node C then reaches a gate-low voltage VGL via the charge TFT (TFT3) (step 52). Subsequently, a next Scan Line [Rₙ₊₁] is asserted (step 53), and the voltage at the node C is readout via the readout TFT (TFT2) by the readout circuit 14 (step 54), which integrates and converts the analog signals into digital signals. The absence or presence of a finger could be distinguished according to different output Vₒᵤₜ of the integrator OP-Amp 147 due to different C_{touch}. The converted digital signals are subsequently, in step 55, forwarded to the image processing circuit 16 to determine the location and image of the finger(s).

Although specific embodiments have been illustrated and described, it will be appreciated by those skilled in the art that various modifications may be made without departing from the scope of the present invention, which is intended to be limited solely by the appended claims.

What is claimed is:

1. A sensor, comprising:
an active matrix area having a plurality of sensor pixel circuits arranged in matrix form; and
a plurality of scan lines and readout lines arranged in the active matrix area such that the scan lines and the readout lines respectively cross each other at one of the sensor pixel circuits,
wherein each of the sensor pixel circuits includes a touch capacitor, a charge TFT for storing charge at the touch capacitor according to a previous scan line, and a readout TFT for reading out voltage across the touch capacitor according to a present scan line.

2. The sensor according to claim 1, further comprising a scan driver for sequentially asserting the scan lines.

3. The sensor according to claim 1, further comprising a readout circuit for analyzing analog signals outputted from the active matrix area, and then converting the analog signals into digital signals.

4. The sensor according to claim 1, further comprising an image processing circuit for determining location and image of the object or objects.

5. The sensor according to claim 3, wherein the readout circuit comprises:
a plurality of integrating circuits connected to receive output of the active matrix area, wherein the integrating circuits respectively connect to the readout lines.

6. The sensor according to claim 5, wherein each of the integrating circuits comprises:
an integrator operational amplifier;
a feedback capacitor connected between output and inverting input of the integrator operational amplifier;
a predetermined reset voltage connected to non-inverting input of the integrator operational amplifier; and
a reset transistor having source and drain connected across ends of the feedback capacitor, and a gate connected to a reset signal.

7. The sensor according to claim 6, wherein the readout circuit further comprises:
a multiplexer for inputting the outputs of the integrator operational amplifiers, among which one of the outputs is selected according to readout line selecting signals; and
a comparator for comparing the analog signal of the selected readout line with a predetermined reference voltage.

8. The sensor according to claim 1, wherein:
the readout TFT having one of source/drain being electrically connected to associated readout line, gate being electrically connected to the associated scan line of present row, and other one of the source/drain being electrically connected to the charge TFT and the touch capacitor at a node;
the charge TFT having one of source/drain being electrically connected to the readout TFT at the node, gate being electrically connected to the associated scan line of previous row, and the other one of the source/drain being electrically connected to the associated scan line of the present row; and
the touch capacitor having one plate being electrically connected to the node and other plate being electrically connected to a common voltage.

9. A sensing method, comprising:
asserting a scan line of previous row;
reaching a low voltage at a node of present row;
asserting a scan line of present row;
reading out voltage at the node of the present row; and
integrating the readout voltage, thereby absence or presence of an object is distinguishable according to different integrated readout voltage due to different touch capacitance at the node.

10. The sensing method according to claim 9, further comprising:
converting analog signals of the integrated readout voltages into digital signals.

11. The sensing method according to claim 10, further comprising:
processing the digital signals to determine location and image of the object or objects.
